(19) United States
(12) Patent Application Publication
(10) Pub. No.: US 2022/0239280 A1
(43) Pub. Date: Jul. 28, 2022

(54) ACOUSTIC WAVE FILTER

(71) Applicant: Murata Manufacturing Co., Ltd., Nagaokakyo-shi (JP)

(72) Inventor: Shuichi KAWANO, Nagaokakyo-shi (JP)

(21) Appl. No.: 17/720,342

(22) Filed: Apr. 14, 2022

Related U.S. Application Data
(63) Continuation of application No. PCT/JP2020/040849, filed on Oct. 30, 2020.

(30) Foreign Application Priority Data
Oct. 31, 2019 (JP) 2019-199253

(51) Int. Cl. H03H 9/64; H03H 9/02; H03H 9/145; H03H 9/25

(52) U.S. Cl. CPC H03H 9/6433; H03H 9/02992; H03H 9/02559; H03H 9/25; H03H 9/145

(57) ABSTRACT

An acoustic wave filter includes a surface acoustic wave resonator and a bulk acoustic wave resonator. The SAW resonator includes a piezoelectric substrate and an interdigital transducer electrode on the substrate. The IDT electrode includes a pair of comb-shaped electrodes interdigitated with each other. Each comb-shaped electrode includes electrode fingers extending in parallel or substantially in parallel in a direction crossing the SAW propagation direction and a busbar electrode connecting the electrode fingers to each other at one end of each of the electrode fingers. The BAW resonator includes a lower electrode defined by a portion of a busbar electrode, a piezoelectric film on the busbar electrode, and an upper electrode on the piezoelectric film.

### CROSS REFERENCE TO RELATED APPLICATIONS

This application claims the benefit of priority to Japanese Patent Application No. 2019-199253 filed on Oct. 31, 2019 and is a Continuation Application of PCT Application No. PCT/JP2020/040849 filed on Oct. 30, 2020. The entire contents of each application are hereby incorporated herein by reference.

### BACKGROUND OF THE INVENTION

### 1. Field of the Invention

The present invention relates to an acoustic wave filter including a surface acoustic wave resonator and a bulk acoustic wave resonator.

### 2. Description of the Related Art

Low-loss and high-attenuation acoustic wave filters such as longitudinally coupled surface acoustic wave (SAW) filters and SAW ladder filters are used in communication devices, including mobile phones. In recent years, along with the development of multiband operation of communication devices, demand has increased for miniaturized acoustic wave filters usable in various frequency bands.

Japanese Unexamined Patent Application Publication No. 2007-037102 discloses an integrated filter constructed by forming a SAW resonator and a bulk acoustic wave (BAW) resonator on the same substrate. This can obtain an acoustic wave filter usable in various frequency ranges.

In the integrated filter disclosed in Japanese Unexamined Patent Application Publication No. 2007-037102, however, the SAW resonator and the BAW resonator are formed in different areas on the substrate, and thus, a problem arises in which the size of the filter is increased.

### SUMMARY OF THE INVENTION

Preferred embodiments of the present invention provide miniaturized acoustic wave filters each including a SAW resonator and a BAW resonator.

An acoustic wave filter according to a preferred embodiment of the present invention includes a surface acoustic wave resonator and a bulk acoustic wave resonator. The surface acoustic wave resonator includes a substrate with piezoelectricity and an interdigital transducer (IDT) electrode on the substrate. The IDT electrode includes a pair of comb-shaped electrodes interdigitated with each other. Each of the pair of comb-shaped electrodes includes a plurality of electrode fingers extending parallel or substantially parallel in a direction crossing a surface acoustic wave propagation direction and a busbar electrode connecting the plurality of electrode fingers to each other at one end of each electrode finger of the plurality of electrode fingers. The bulk acoustic wave resonator includes a lower electrode including a portion of the busbar electrode, a piezoelectric film on the busbar electrode, and an upper electrode on the piezoelectric film.

Each of the acoustic wave filters according to preferred embodiments of the present invention is able to provide a miniaturized acoustic wave filter including a SAW resonator and a BAW resonator.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A and 1B provide plan views of an electrode and a sectional view of a structure that illustrate a basic structure of an acoustic wave filter according to a first preferred embodiment of the present invention.

FIGS. 2A and 2B provide plan views of electrodes and a sectional view of a structure of an acoustic wave filter according to a first practical example of a preferred embodiment of the present invention.

FIGS. 3A and 3B provide circuit configuration diagrams of the acoustic wave filter according to the first practical example and a graph illustrating a comparison between the acoustic wave filter according to the first practical example and an acoustic wave filter according to a first comparative example with respect to the bandpass characteristic.

FIGS. 4A and 4B provide circuit configuration diagrams and a plan view of electrodes of an acoustic wave filter according to a first modification of a preferred embodiment of the present invention.

FIGS. 5A and 5B provide circuit configuration diagrams and a plan view of electrodes of an acoustic wave filter according to a second modification of a preferred embodiment of the present invention.

FIGS. 6A and 6B provide circuit configuration diagrams and a plan view of electrodes of an acoustic wave filter according to a third modification of a preferred embodiment of the present invention.

FIGS. 7A and 7B provide plan views of electrodes and a sectional view of a structure of an acoustic wave filter according to a second practical example of a preferred embodiment of the present invention.

FIGS. 8A and 8B provide circuit configuration diagrams of the acoustic wave filter according to the second practical example and a graph illustrating a comparison between the acoustic wave filter according to the second practical example and an acoustic wave filter according to a second comparative example with respect to the bandpass characteristic.

FIGS. 9A and 9B provide circuit configuration diagrams and a plan view of electrodes of an acoustic wave filter according to a fourth modification of a preferred embodiment of the present invention.

FIGS. 10A and 10B provide circuit configuration diagrams and a plan view of electrodes of an acoustic wave filter according to a fifth modification of a preferred embodiment of the present invention.

FIGS. 11A and 11B provide circuit configuration diagrams and a plan view of electrodes of an acoustic wave filter according to a sixth modification of a preferred embodiment of the present invention.

FIGS. 12A to 12C provide graphs illustrating bandpass characteristics with respect to different film thicknesses of the piezoelectric film of the acoustic wave filter according to the first practical example.

FIGS. 13A to 13D provide plan views of electrodes illustrating variations of the shape of a piezoelectric film of an acoustic wave filter according to a preferred embodiment of the present invention.

### DETAILED DESCRIPTION OF THE PREFERRED EMBODIMENTS

Hereinafter, preferred embodiments of the present invention will be described in detail with reference to the drawings. The preferred embodiments described below are comprehensive or specific examples. Specific features including numerical values, shapes, materials, elements, arrangements of the elements, and connection configurations described in the following preferred embodiments are mere examples and are not intended to limit the present invention. Among the elements in the following preferred embodiments, elements not recited in any of the independent claims are described as arbitrary or optional elements. The size or size ratio of the elements illustrated in the drawings is not necessarily presented in an exact manner.

### Preferred Embodiment

### 1. Basic Structure of Acoustic Wave Filter 1

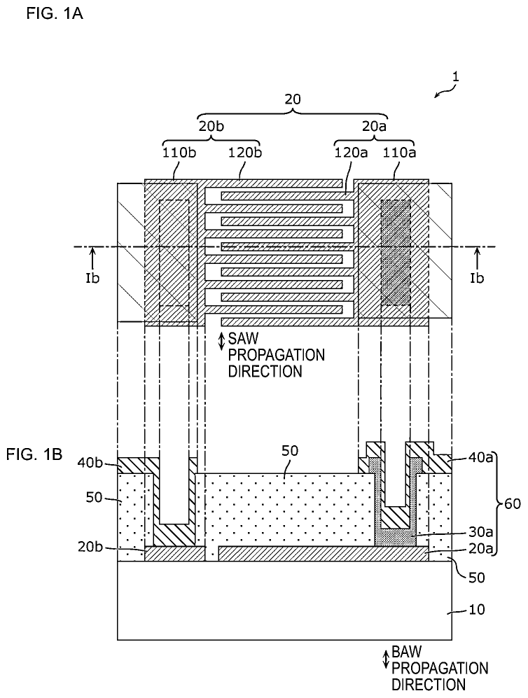

FIGS. 1A and 1B provide plan views of an electrode and a sectional view of a structure that illustrate a basic structure of an acoustic wave filter 1 according to a first preferred embodiment. In the drawings, FIG. 1A is a plan view of elements including an interdigital transducer (IDT) electrode when a substrate 10 is viewed in plan view, and FIG. 1B is a sectional view taken along line Ib-Ib in FIG. 1A. As illustrated in the drawings, the acoustic wave filter 1 includes the substrate 10 having piezoelectricity, an IDT electrode 20, a piezoelectric film 30a, upper electrodes 40a and 40b, and a protective layer 50.

The substrate 10 is a substrate having piezoelectricity, such as, for example, a single-crystal piezoelectric substrate made of a piezoelectric material. Examples of the single-crystal piezoelectric substrate include piezoelectric single crystals, such as LiNbO₃ and LiTaO₃, and quartz-crystal.

The substrate 10 is not necessarily a single piezoelectric layer. The substrate 10 may include a high acoustic velocity support substrate, a low acoustic velocity film, and a piezoelectric film that are stacked in this order. The piezoelectric film in this case may be made of, for example, a piezoelectric single crystal or piezoelectric ceramic. The high acoustic velocity support substrate supports elements including the low acoustic velocity film, the piezoelectric film, and the IDT electrode 20. The acoustic velocity of bulk waves in the high acoustic velocity support substrate is higher than the acoustic velocity of surface acoustic waves and boundary waves propagating along the piezoelectric film. The function of this structure is that the multilayer body of the piezoelectric film and the low acoustic velocity film confine surface acoustic waves so that the surface acoustic waves are prevented from leaking into the portion including the high acoustic velocity support substrate and portions lower than the high acoustic velocity support substrate. The high acoustic velocity support substrate may be, for example, a silicon substrate. In the low acoustic velocity film, bulk waves propagate at an acoustic velocity lower than bulk waves propagating in the piezoelectric film. The low acoustic velocity film is disposed between the piezoelectric film and the high acoustic velocity support substrate. This structure and a property of acoustic wave in which energy is naturally concentrated in low-acoustic-velocity media hinder leakage of surface acoustic wave energy outside the IDT electrode 20. The low acoustic velocity film may be mainly made of, for example, silicon dioxide. By comparison to a single-layer piezoelectric substrate, the layered structure of the substrate 10 described above can increase the Q factor at the resonant frequency and anti-resonant frequency of a surface acoustic wave resonator. As such, an acoustic wave resonator with a relatively high Q factor can be provided, and as a result, a filter with low insertion loss can be provided by using the acoustic wave resonator.

The high acoustic velocity support substrate may have a structure provided by stacking a support substrate and a high acoustic velocity film in which bulk waves propagate at an acoustic velocity higher than acoustic waves such as surface acoustic waves and boundary waves propagating along the piezoelectric film. In this case, examples of a material used for the support substrate include piezoelectric materials such as sapphire, lithium tantalate, lithium niobate, and quartz-crystal, various ceramics such as alumina, magnesia, silicon nitride, aluminum nitride, silicon carbide, zirconia, cordierite, mullite, steatite, and forsterite, dielectric materials such as glass, semiconductors such as silicon and gallium nitride, and resin substrates. The high acoustic velocity film may include various high-acoustic-velocity materials including, for example, aluminum nitride, aluminum oxide, silicon carbide, silicon nitride, silicon oxynitride, DLC films, or diamond, a medium mainly including the above material, and a medium mainly including a mixture of the above materials.

The substrate 10 may include a support substrate, an energy confining layer, and a piezoelectric film that are stacked in this order. The IDT electrode 20 may be provided on the piezoelectric film. For example, a piezoelectric single crystal or piezoelectric ceramic may be used for the piezoelectric film. The support substrate supports the piezoelectric film, the energy confining layer, and the IDT electrode 20. The energy confining layer includes one or more layers. The velocity of bulk acoustic waves propagating in at least one layer of the layers is higher than the velocity of acoustic waves propagating close to the piezoelectric film. For example, the energy confining layer may have a layered structure including a low acoustic velocity layer and a high acoustic velocity layer. The acoustic velocity of bulk waves in the low acoustic velocity layer is lower than the acoustic velocity of acoustic waves propagating in the piezoelectric film. The acoustic velocity of bulk waves in the high acoustic velocity layer is higher than the acoustic velocity of acoustic waves propagating in the piezoelectric film. The support substrate may be defined by a high acoustic velocity layer. The energy confining layer may be an acoustic impedance layer provided by alternately layering a low acoustic impedance layer with a relatively low acoustic impedance and a high acoustic impedance layer with a relatively high acoustic impedance.

The IDT electrode 20 includes a pair of comb-shaped electrodes 20a and 20b that are provided on the substrate 10 and that are interdigitated with each other. The comb-shaped electrode 20a extends in a direction crossing a surface acoustic wave (SAW) propagation direction. The comb-shaped electrode 20a includes a plurality of electrode fingers 120a disposed parallel or substantially parallel to each other and a busbar electrode 110a connecting the electrode fingers 120a to each other at one end of each electrode finger 120a. The comb-shaped electrode 20b extends in a direction crossing the SAW propagation direction. The comb-shaped electrode 20b includes a plurality of electrode fingers 120b disposed parallel or substantially parallel to each other and a busbar electrode 110b connecting the electrode fingers 120b to each other at one end of each electrode finger 120b.

The IDT electrode 20 has a layered structure including, for example, a fixing layer and a main electrode layer. The fixing layer improves the fixing strength between the substrate 10 and the main electrode layer. An example of the material used for the fixing layer is Ti. An example of the material of the main electrode layer is Al including about 1% Cu. The material of the fixing layer and the material of the main electrode layer are not limited to the materials described above. The IDT electrode 20 is not necessarily defined by the layered structure described above. The IDT electrode 20 may be made of, for example, a metal, such as Ti, Al, Cu, Pt, Au, Ag, or Pd, or an alloy thereof, or may include a plurality of multilayer bodies made of the metal or alloy.

The protective layer 50 is provided on the IDT electrode 20 to cover the comb-shaped electrodes 20a and 20b. The protective layer 50 is used for the following purposes: (1) to protect the main electrode layer of the IDT electrode 20 from the external environment, (2) to control the frequency temperature characteristic, and (3) to increase moisture resistance. The protective layer 50 is a dielectric film mainly made of, for example, silicon dioxide.

In the structure of the acoustic wave filter 1 described above, the substrate 10, the IDT electrode 20, and the protective layer 50 together define a SAW resonator. The SAW resonator exhibits resonance such that surface acoustic waves are excited along a surface of the piezoelectric substrate and in the comb-shaped electrodes by applying electrical energy between the busbar electrodes facing each other. The surface acoustic waves generated in the SAW resonator propagate between the electrode fingers 120a and 120b along the surface of the substrate 10.

The SAW resonator described above does not necessarily include the protective layer 50. A reflector may be provided adjacent to the IDT electrode 20 in the SAW propagation direction.

The piezoelectric film 30a is provided on the busbar electrode 110a. The upper electrode 40a is provided on the piezoelectric film 30a.

The piezoelectric film 30a is mainly made of, for example, at least one of zinc oxide (ZnO), aluminum nitride (AlN), lead zirconate titanate (PZT), potassium niobate (KN), lithium niobate (LN), lithium tantalate (LT), quartz-crystal, and lithium borate (LiBO). When the piezoelectric film 30a is made of zinc oxide (ZnO) or aluminum nitride (AlN), it is preferable that the piezoelectric film 30a is a c-axis oriented film.

The upper electrode 40a is made of, for example, the same material as the main electrode layer of the IDT electrode 20, which may be Al including about 1% Cu.

In the structure of the acoustic wave filter 1 described above, the busbar electrode 110a, the piezoelectric film 30a, and the upper electrode 40a together define a bulk acoustic wave (BAW) resonator. The BAW resonator exhibits resonance such that bulk acoustic waves are excited in the piezoelectric film 30a by applying electrical energy between the busbar electrode 110a and the upper electrode 40a. The busbar electrode 110a defines and functions as a lower electrode of the BAW resonator. The bulk acoustic waves generated in the BAW resonator propagate between the busbar electrode 110a and the upper electrode 40a in the vertical direction relative to the surface of the substrate 10. To define the BAW resonator, the protective layer 50 is disposed between the busbar electrode 110b and the upper electrode 40a so that the busbar electrode 110b is not in direct contact with the upper electrode 40a.

On the busbar electrode 110b, the upper electrode 40b is provided in a cavity above the busbar electrode 110b. As such, the busbar electrode 110b and the upper electrode 40b define two-layer wiring. The two-layer wiring can reduce interconnection resistance, and as a result, it is possible to reduce transmission loss of radio-frequency signal. The upper electrode 40b is made of, for example, the same material as the upper electrode 40a. The upper electrodes 40a and 40b are formed by the same deposition process.

With the structure described above, the acoustic wave filter 1 includes the SAW resonator and the BAW resonator on the same substrate. Additionally, the busbar electrode 110a of the SAW resonator also defines and functions as the lower electrode of the BAW resonator. This means that the SAW resonator and the BAW resonator are provided in a shared area on the substrate 10. Consequently, by comparison to the structure in which a SAW resonator and a BAW resonator are separately provided in discrete areas on a substrate, this structure can reduce the size of the acoustic wave filter 1. Furthermore, the busbar electrode 110a of the SAW resonator and the lower electrode of the BAW resonator can be formed at the same time, and additionally, the upper electrode 40b of the two-layer wiring of the SAW resonator and the upper electrode 40a of the BAW resonator can be formed by the same manufacturing process. Accordingly, it is possible to simplify the manufacturing process and also reduce costs.

### 2. Structure of Acoustic Wave Filter According to First Practical Example

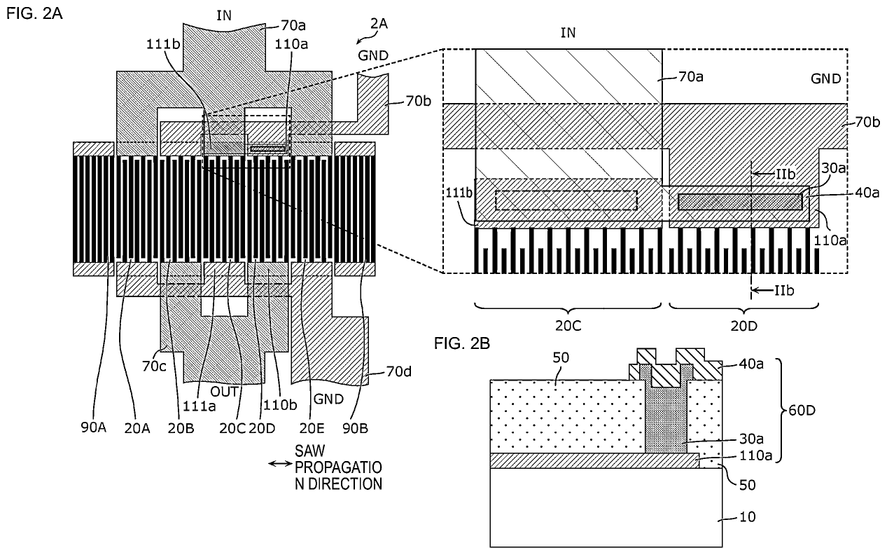

FIGS. 2A and 2B provide plan views of electrodes and a sectional view of a structure of an acoustic wave filter 2A according to a first practical example of a preferred embodiment of the present invention. FIG. 2A provides a plan view of elements including IDT electrodes and reflectors when the substrate 10 is viewed in plan view, and an enlarged plan view of busbar electrodes of adjacent IDT electrodes, and FIG. 2B is a sectional view taken along line IIb-IIb in the enlarged plan view of FIG. 2A.

As illustrated in FIGS. 2A and 2B, the acoustic wave filter 2A includes the substrate 10 with piezoelectricity, IDT electrodes 20A, 20B, 20C, 20D, and 20E, reflectors 90A and 90B, the piezoelectric film 30a, the upper electrode 40a, and the protective layer 50.

As illustrated in FIG. 2A, the IDT electrodes 20A to 20E each include a pair of comb-shaped electrodes. Each comb-shaped electrode includes a plurality of electrode fingers extending in a direction crossing the SAW propagation direction and a busbar electrode connecting the electrode fingers to each other at one end of each electrode finger. The pair of comb-shaped electrodes face each other such that the electrode fingers are interdigitated with each other. The IDT electrodes 20A to 20E are disposed between the reflectors 90A and 90B in the SAW propagation direction.

The IDT electrodes 20A to 20E and the reflectors 90A and 90B are arranged in the SAW propagation direction in the following order: the reflector 90A, the IDT electrodes 20A, 20B, 20C, 20D, and 20E, and the reflector 90B. Of each of the IDT electrodes 20A, 20C, and 20E, the busbar electrode on one side of the pair of comb-shaped electrodes is coupled to an input-side wire 70a. Of each of the IDT electrodes 20B and 20D, the busbar electrode on the other side of the pair of comb-shaped electrodes is coupled to an input-side ground wire 70b. Of each of the IDT electrodes 20A, 20C, and 20E, the busbar electrode on the other side of the pair of comb-shaped electrodes is coupled to an output-side ground wire 70d. Of each of the IDT electrodes 20B and 20D, the busbar electrode on the one side of the pair of comb-shaped electrodes is coupled to an output-side wire 70c. With the structure described above, in the acoustic wave filter 2A according to the present practical example, the substrate 10, the IDT electrodes 20A to 20E, and the reflectors 90A and 90B include a longitudinally coupled resonator including five SAW resonators.

Here, as illustrated in the enlarged plan view in FIG. 2A, the piezoelectric film 30a is provided on the busbar electrode 110a of the IDT electrode 20D of the adjacent IDT electrodes 20C and 20D. The upper electrode 40a is provided on the piezoelectric film 30a. The busbar electrode 110a is connected to the input-side ground wire 70b. The upper electrode 40a is connected to the input-side wire 70a. Although FIG. 2A does not illustrate the protective layer 50, the protective layer 50 is disposed between the busbar electrode 110a and the upper electrode 40a.

In the structure of the acoustic wave filter 2A, as illustrated in FIG. 2B, the busbar electrode 110a, the piezoelectric film 30a, and the upper electrode 40a together define a BAW resonator 60D. The busbar electrode 110a defines and functions as a lower electrode of the BAW resonator 60D. The bulk acoustic waves generated in the BAW resonator 60D propagate between the busbar electrode 110a and the upper electrode 40a in the vertical direction relative to the surface of the substrate 10.

The upper electrode 40a is directly connected to a busbar electrode 111b of the IDT electrode 20C. This means that the busbar electrode 111b and the upper electrode 40a define a two-layer wiring on the busbar electrode 111b. As such, the busbar electrode 111b is coupled to the input-side wire 70a.

As described above, in the acoustic wave filter 2A according to the present practical example, the piezoelectric film 30a is provided on the busbar electrode 110a connected to the input-side ground wire 70b, and the upper electrode 40a is provided on the piezoelectric film 30a and on the adjacent busbar electrode 111b coupled to the input-side wire 70a.

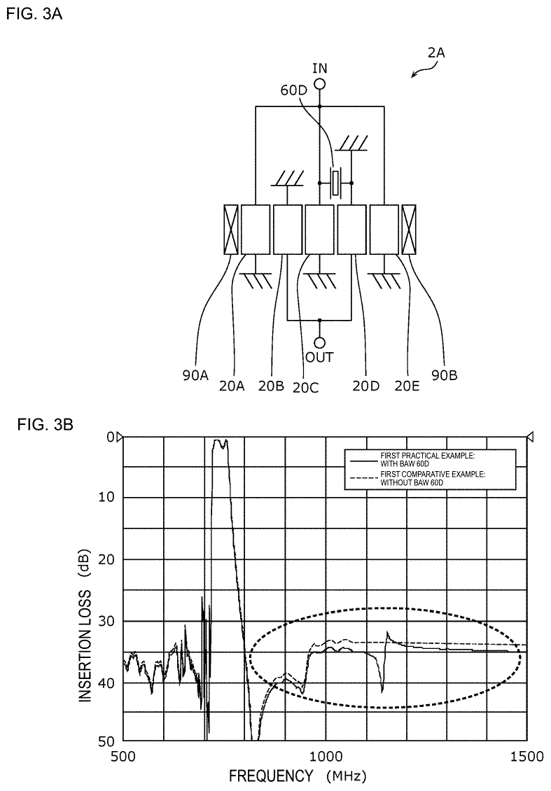

FIGS. 3A and 3B provide circuit configuration diagrams of the acoustic wave filter 2A according to the first practical example and a graph illustrating a comparison between the acoustic wave filter according to the first practical example and an acoustic wave filter according to a first comparative example with respect to the bandpass characteristic. The acoustic wave filter according to the first comparative example has a structure provided by removing the BAW resonator 60D from the acoustic wave filter 2A according to the first practical example.

As illustrated in FIG. 3A, the acoustic wave filter 2A according to the present practical example includes the BAW resonator 60D between the busbar electrode 110a at a ground potential of the IDT electrode 20D and the input-side busbar electrode 111b at a HOT potential of the IDT electrode 20C, in addition to the longitudinally coupled resonator including the SAW resonators that include the IDT electrodes 20A to 20E.

As illustrated in FIG. 3B, there is almost no difference between the acoustic wave filter 2A according to the first practical example and the acoustic wave filter according to the first comparative example with respect to the insertion loss in a pass band. This is because the longitudinally coupled resonator effects characteristics in the pass band. In contrast, in an attenuation band higher than the pass band, the acoustic wave filter 2A according to the first practical example is greater with respect to attenuation. It is concluded that attenuation outside the band is improved because oscillations caused by vibrations of bulk acoustic waves generated in the BAW resonator 60D occur at frequencies higher than the pass band.

The number of IDT electrodes of the acoustic wave filter 2A is not limited to five. The number of IDT electrodes constituting the acoustic wave filter 2A only needs to be, for example, three or more. Additionally, two or more BAW resonators may be provided to define the acoustic wave filter 2A.

In the structure of the acoustic wave filter 2A according to the first practical example, the SAW resonator defining the longitudinally coupled resonator and the BAW resonator 60D are provided at the same substrate 10. Additionally, the busbar electrode 110a of the SAW resonator also defines and functions as the lower electrode of the BAW resonator 60D. This means that the SAW resonator and the BAW resonator 60D are provided in a shared area on the substrate 10. Consequently, in comparison to the structure in which the SAW resonators and the BAW resonator 60D are separately provided in discrete areas on a substrate, this structure can improve the attenuation characteristic of the acoustic wave filter 2A and also make the acoustic wave filter 2A smaller. Furthermore, the busbar electrode 110a of the SAW resonator and the lower electrode of the BAW resonator 60D can be formed at the same time, and additionally, the upper electrode of the busbar electrode 111b of the SAW resonator and the upper electrode of the BAW resonator 60D can be defined by the same upper electrode 40a. Accordingly, it is possible to simplify the manufacturing process and also reduce costs.

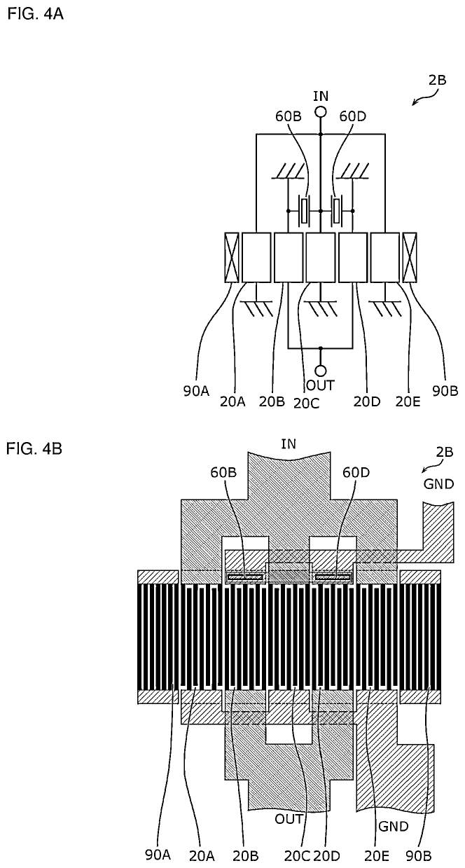

FIGS. 4A and 4B provide circuit configuration diagrams and a plan view of electrodes of an acoustic wave filter 2B according to a first modification of a preferred embodiment of the present invention. The acoustic wave filter 2B illustrated in FIGS. 4A and 4B differs from the acoustic wave filter 2A according to the first practical example in that it includes two BAW resonators 60B and 60D. The following description of the acoustic wave filter 2B according to the present modification omits the same or corresponding configurations as the acoustic wave filter 2A according to the first practical example and mainly focuses on configurations different from the acoustic wave filter 2A.

As illustrated in FIG. 4A, the acoustic wave filter 2B according to the present modification includes the BAW resonators 60B and 60D in addition to the longitudinally coupled resonator defined by the SAW resonators including the IDT electrodes 20A to 20E. The BAW resonator 60B is provided between the busbar electrode (lower electrode) at the ground potential of the IDT electrode 20B and an upper electrode coupled to the busbar electrode at the HOT potential of the IDT electrode 20C. The BAW resonator 60D is provided between the busbar electrode (lower electrode) at the ground potential of the IDT electrode 20D and the upper electrode coupled to the busbar electrode at the HOT potential of the IDT electrode 20C.

In comparison to an acoustic wave filter including a single BAW resonator, the acoustic wave filter 2B according to the first modification can increase attenuation in the attenuation band because the acoustic wave filter 2B includes the two BAW resonators 60B and 60D. When the piezoelectric film of the BAW resonator 60B is provided differently from the piezoelectric film of the BAW resonator 60D with respect to thickness, attenuation can be achieved in two kinds of different attenuation bands. As a result, in comparison to the structure in which the SAW resonators and the BAW resonators are separately provided in discrete areas on a substrate, this structure can further improve the attenuation characteristic of the acoustic wave filter 2B and also make the acoustic wave filter 2B smaller.

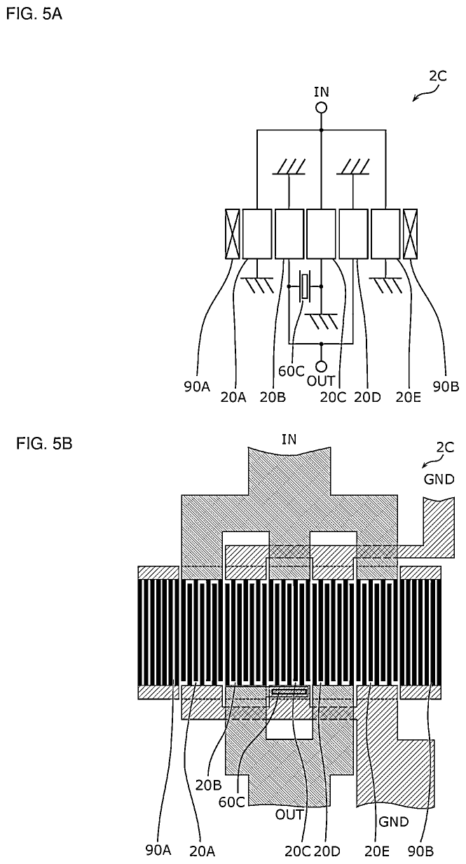

FIGS. 5A and 5B provide circuit configuration diagrams and a plan view of electrodes of an acoustic wave filter 2C according to a second modification of a preferred embodiment of the present invention. The acoustic wave filter 2C illustrated in FIGS. 5A and 5B differs from the acoustic wave filter 2A according to the first practical example in that a BAW resonator 60C is coupled on the output-side instead of the input-side with respect to the longitudinally coupled resonator. The following description of the acoustic wave filter 2C according to the present modification omits the same or corresponding configurations as the acoustic wave filter 2A according to the first practical example and mainly focuses on configurations different from the acoustic wave filter 2A.

As illustrated in FIG. 5A, the acoustic wave filter 2C according to the present modification includes the BAW resonator 60C in addition to the longitudinally coupled resonator composed of the SAW resonators including the IDT electrodes 20A to 20E. The BAW resonator 60C is provided between the busbar electrode (lower electrode) at the ground potential of the IDT electrode 20C and an upper electrode coupled to the output-side busbar electrode at a HOT potential of the IDT electrode 20B.

The acoustic wave filter 2C according to the second modification can increase attenuation in the attenuation band because the BAW resonator 60C is disposed on the output-side with respect to the longitudinally coupled resonator. As a result, in comparison to the structure in which the SAW resonators and the BAW resonators are separately provided in discrete areas on a substrate, this structure can further improve the attenuation characteristic of the acoustic wave filter 2C and also make the acoustic wave filter 2C smaller.

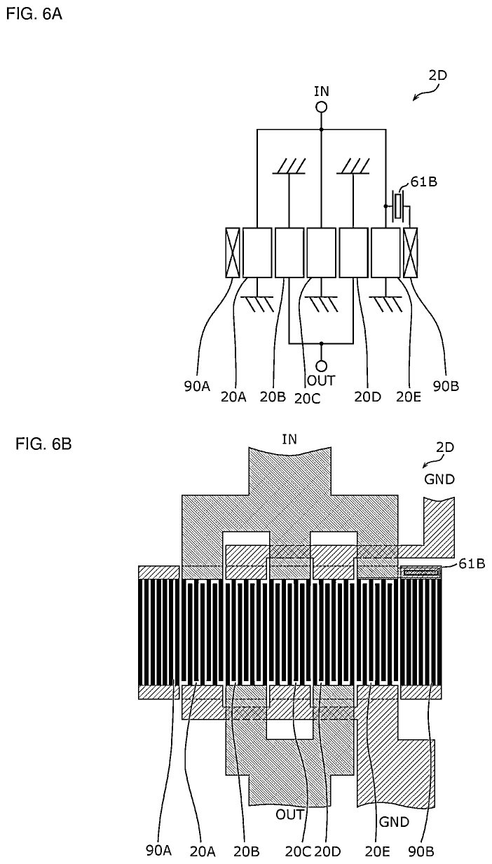

FIGS. 6A and 6B provide circuit configuration diagrams and a plan view of electrodes of an acoustic wave filter 2D according to a third modification of a preferred embodiment of the present invention. The acoustic wave filter 2D illustrated in FIGS. 6A and 6B differs from the acoustic wave filter 2A according to the first practical example in that a BAW resonator 61B is coupled between an IDT electrode and a reflector instead of between IDT electrodes of the longitudinally coupled resonator. The following description of the acoustic wave filter 2D according to the present modification omits the same or corresponding configurations as the acoustic wave filter 2A according to the first practical example and mainly focuses on configurations different from the acoustic wave filter 2A.

As illustrated in FIG. 6A, the acoustic wave filter 2D according to the present modification includes the BAW resonator 61B in addition to the longitudinally coupled resonator composed of the SAW resonators including the IDT electrodes 20A to 20E. The BAW resonator 61B is provided between a busbar electrode of the reflector 90B and an upper electrode coupled to an input-side busbar electrode at the HOT potential of the IDT electrode 20E.

The acoustic wave filter 2D according to the third modification can increase attenuation in the attenuation band because the BAW resonator 61B is disposed between an IDT electrode and a reflector on the input-side with respect to the longitudinally coupled resonator. As a result, in comparison to the structure in which the SAW resonators and the BAW resonators are separately provided in discrete areas on a substrate, this structure can further improve the attenuation characteristic of the acoustic wave filter 2D and also make the acoustic wave filter 2D smaller.

### 3. Structure of Acoustic Wave Filter According to Second Practical Example

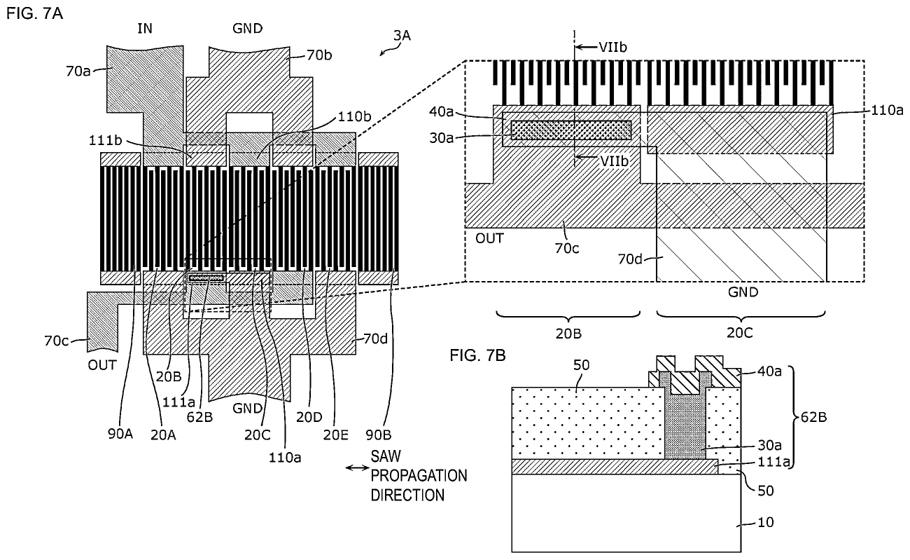

FIGS. 7A and 7B provide plan views of electrodes and a sectional view of a structure of an acoustic wave filter 3A according to a second practical example of a preferred embodiment of the present invention. FIG. 7A provides a plan view of elements including IDT electrodes and reflectors when the substrate 10 is viewed in plan view, and an enlarged plan view of busbar electrodes of adjacent IDT electrodes, and FIG. 7B is a sectional view taken along line VIIb-VIIb in the enlarged plan view of FIG. 7A.

As illustrated in FIGS. 7A and 7B, the acoustic wave filter 3A includes the substrate 10 with piezoelectricity, the IDT electrodes 20A, 20B, 20C, 20D, and 20E, the reflectors 90A and 90B, the piezoelectric film 30a, the upper electrode 40a, and the protective layer 50. The acoustic wave filter 3A according to the present practical example differs from the acoustic wave filter 2A according to the first practical example in that a lower electrode of a BAW resonator is coupled to a HOT wire while an upper electrode is coupled to a ground wire. The following description of the acoustic wave filter 3A according to the present practical example omits the same or corresponding configurations as the acoustic wave filter 2A according to the first practical example and mainly focuses on configurations different from the acoustic wave filter 2A.

As illustrated in the enlarged plan view in FIG. 7A, the piezoelectric film 30a is provided on a busbar electrode 111a of the IDT electrode 20B of the adjacent IDT electrodes 20B and 20C. The upper electrode 40a is provided on the piezoelectric film 30a. The busbar electrode 111a is connected to the output-side wire 70c. The upper electrode 40a is connected to the output-side ground wire 70d. Although FIG. 7A does not illustrate the protective layer 50, the protective layer 50 is disposed between the busbar electrode 111a and the upper electrode 40a.

In the structure of the acoustic wave filter 3A, as illustrated in FIG. 7B, the busbar electrode 111a, the piezoelectric film 30a, and the upper electrode 40a together define a BAW resonator 62B. The busbar electrode 111a defines and functions as a lower electrode of the BAW resonator 62B. The bulk acoustic waves generated in the BAW resonator 62B propagate between the busbar electrode 111a and the upper electrode 40a in the vertical direction relative to the surface of the substrate 10.

The upper electrode 40a is directly connected to the busbar electrode 110a of the IDT electrode 20C. This means that the busbar electrode 110a and the upper electrode 40a define a two-layer wiring on the busbar electrode 110a. As such, the busbar electrode 110a is coupled to the output-side wire 70c.

As described above, in the acoustic wave filter 3A according to the present practical example, the piezoelectric film 30a is provided on the busbar electrode 111a coupled to the output-side wire 70c, and the upper electrode 40a is provided on the piezoelectric film 30a and on the busbar electrode 110a coupled to the output-side ground wire 70d.

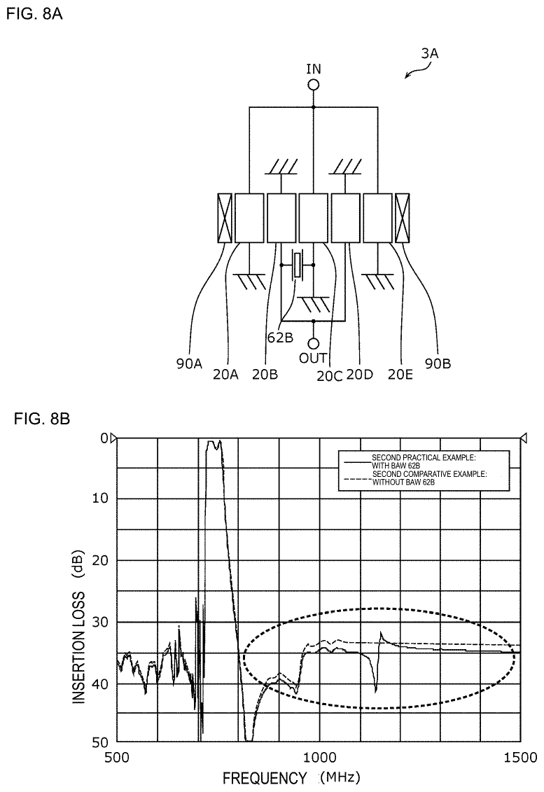

FIGS. 8A and 8B provide circuit configuration diagrams of the acoustic wave filter 3A according to the second practical example and a graph illustrating the comparison between the acoustic wave filter according to the second practical example and an acoustic wave filter according to a second comparative example with respect to the bandpass characteristic. The acoustic wave filter according to the second comparative example has a structure provided by removing the BAW resonator 62B from the acoustic wave filter 3A according to the second practical example.

As illustrated in FIG. 8A, the acoustic wave filter 3A according to the present practical example includes the BAW resonator 62B provided between the busbar electrode 111a at the HOT potential of the IDT electrode 20B and the output-side busbar electrode 110a at the ground potential of the IDT electrode 20C, in addition to the longitudinally coupled resonator defined by the SAW resonators including the IDT electrodes 20A to 20E.

As illustrated in FIG. 8B, there is almost no difference between the acoustic wave filter 3A according to the second practical example and the acoustic wave filter according to the second comparative example with respect to the insertion loss in a pass band. This is because the longitudinally coupled resonator effects characteristics in the pass band. In contrast, in an attenuation band higher than the pass band, the acoustic wave filter 3A according to the second practical example is greater with respect to attenuation. It is concluded that attenuation outside the band is improved because oscillations caused by vibrations of bulk acoustic waves generated in the BAW resonator 62B occur at frequencies higher than the pass band.

The number of IDT electrodes of the acoustic wave filter 3A is not limited to five. The number of IDT electrodes constituting the acoustic wave filter 3A only needs to be, for example, three or more. Additionally, for example, two or more BAW resonators may be provided to define the acoustic wave filter 3A.

In the structure of the acoustic wave filter 3A according to the second practical example, the SAW resonator defining the longitudinally coupled resonator and the BAW resonator 62B are provided at the same substrate 10. Additionally, the busbar electrode 111a of the SAW resonator also defines and functions as the lower electrode of the BAW resonator 62B. This means that the SAW resonator and the BAW resonator 62B are provided in a shared area on the substrate 10. Consequently, in comparison to the structure in which the SAW resonators and the BAW resonator 62B are separately provided in discrete areas on a substrate, this structure can improve the attenuation characteristic of the acoustic wave filter 3A and also make the acoustic wave filter 3A smaller. Furthermore, the busbar electrode 111a of the SAW resonator and the lower electrode of the BAW resonator 62B can be formed at the same time, and additionally, the upper electrode of the busbar electrode 110a of the SAW resonator and the upper electrode of the BAW resonator 62B can be provided by the same upper electrode 40a. Accordingly, it is possible to simplify the manufacturing process and also reduce costs.

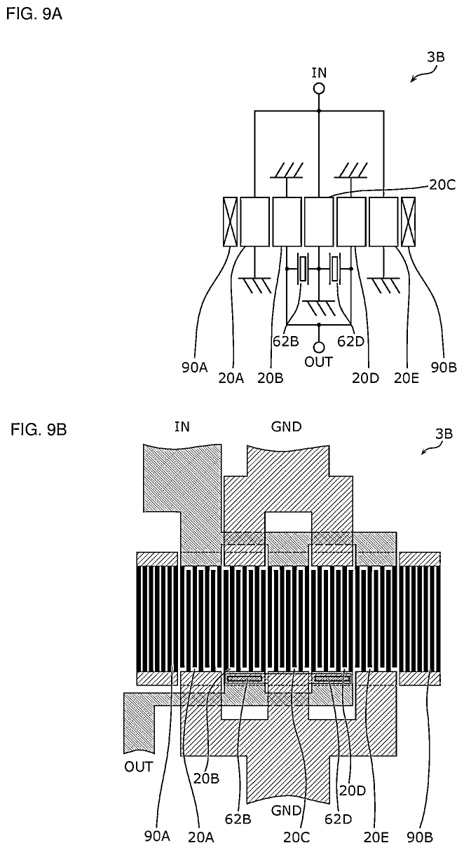

FIGS. 9A and 9B provide circuit configuration diagrams and a plan view of electrodes of an acoustic wave filter 3B according to a fourth modification of a preferred embodiment of the present invention. The acoustic wave filter 3B illustrated in the drawing differs from the acoustic wave filter 3A according to the second practical example in that it includes two BAW resonators 62B and 62D. The following description of the acoustic wave filter 3B according to the present modification omits the same or corresponding configurations as the acoustic wave filter 3A according to the second practical example and mainly focuses on configurations different from the acoustic wave filter 3A.

As illustrated in FIG. 9A, the acoustic wave filter 3B according to the present modification includes the BAW resonators 62B and 62D in addition to the longitudinally coupled resonator composed of the SAW resonators including the IDT electrodes 20A to 20E. The BAW resonator 62B is provided between the busbar electrode (lower electrode) at the HOT potential of the IDT electrode 20B and an upper electrode coupled to the busbar electrode at the ground potential of the IDT electrode 20C. The BAW resonator 62D is provided between the busbar electrode (lower electrode) at the HOT potential of the IDT electrode 20D and the upper electrode coupled to the busbar electrode at the ground potential of the IDT electrode 20C.

In comparison to an acoustic wave filter including a single BAW resonator, the acoustic wave filter 3B according to the fourth modification can increase attenuation in the attenuation band because the acoustic wave filter 3B includes the two BAW resonators 62B and 62D. When the piezoelectric film of the BAW resonator 62B is formed differently from the piezoelectric film of the BAW resonator 62D with respect to thickness, attenuation can be achieved in two kinds of attenuation bands of different frequencies. As a result, in comparison to the structure in which the SAW resonators and the BAW resonators are separately provided in discrete areas on a substrate, this structure can further improve the attenuation characteristic of the acoustic wave filter 3B and also make the acoustic wave filter 3B smaller.

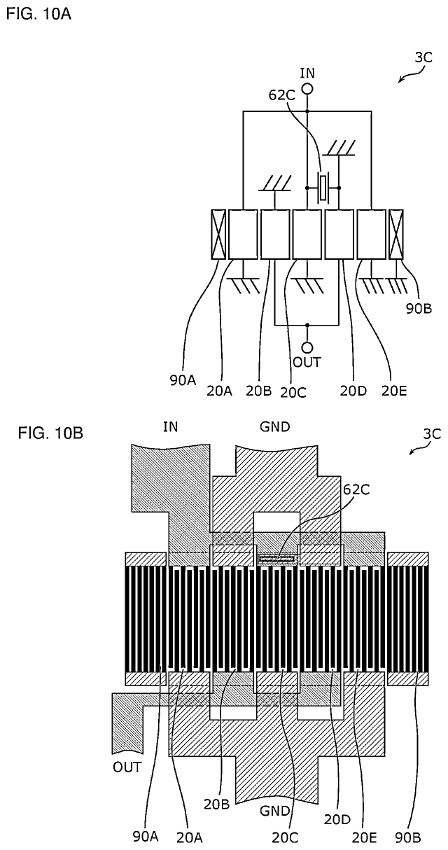

FIGS. 10A and 10B provide circuit configuration diagrams and a plan view of electrodes of an acoustic wave filter 3C according to a fifth modification of a preferred embodiment of the present invention. The acoustic wave filter 3C illustrated in the drawing differs from the acoustic wave filter 3A according to the second practical example in that a BAW resonator 62C is coupled on the input-side instead of the output-side with respect to the longitudinally coupled resonator. The following description of the acoustic wave filter 3C according to the present modification omits the same or corresponding configurations as the acoustic wave filter 3A according to the second practical example and mainly focuses on configurations different from the acoustic wave filter 3A.

As illustrated in FIG. 10A, the acoustic wave filter 3C according to the present modification includes the BAW resonator 62C in addition to the longitudinally coupled resonator composed of the SAW resonators including the IDT electrodes 20A to 20E. The BAW resonator 62C is provided between the busbar electrode (lower electrode) at the HOT potential of the IDT electrode 20C and an upper electrode coupled to the input-side busbar electrode at the ground potential of the IDT electrode 20D.

The acoustic wave filter 3C according to the fourth modification can increase attenuation in the attenuation band because the BAW resonator 62C is disposed on the input-side with respect to the longitudinally coupled resonator. As a result, in comparison to the structure in which the SAW resonators and the BAW resonators are separately provided in discrete areas on a substrate, this structure can further improve the attenuation characteristic of the acoustic wave filter 3C and also make the acoustic wave filter 3C smaller.

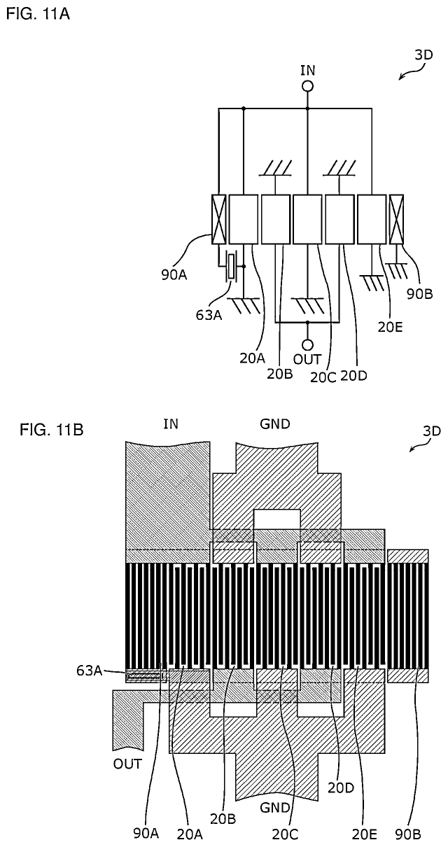

FIGS. 11A and 11B provide circuit configuration diagrams and a plan view of electrodes of an acoustic wave filter 3D according to a sixth modification of a preferred embodiment of the present invention. The acoustic wave filter 3D illustrated in the drawing differs from the acoustic wave filter 3A according to the second practical example in that a BAW resonator 63A is coupled between an IDT electrode and a reflector instead of between IDT electrodes of the longitudinally coupled resonator. The following description of the acoustic wave filter 3D according to the present modification omits the same or corresponding configurations as the acoustic wave filter 3A according to the second practical example and mainly focuses on configurations different from the acoustic wave filter 3A.

As illustrated in FIG. 11A, the acoustic wave filter 3D according to the present modification includes the BAW resonator 63A in addition to the longitudinally coupled resonator defined by the SAW resonators including the IDT electrodes 20A to 20E. The BAW resonator 63A is provided between a busbar electrode on the output-side of the reflector 90A and an upper electrode coupled to an output-side busbar electrode at the ground potential of the IDT electrode 20A.

The acoustic wave filter 3D according to the sixth modification can increase attenuation in the attenuation band because the BAW resonator 63A is disposed between an IDT electrode and a reflector on the output-side with respect to the longitudinally coupled resonator. As a result, by comparison to the structure in which the SAW resonators and the BAW resonators are separately formed in discrete areas on a substrate, this structure can further improve the attenuation characteristic of the acoustic wave filter 3D and also make the acoustic wave filter 3D smaller.

### 4. Relationship Between Piezoelectric Film Thickness and Filter Bandpass Characteristic

Concerning a BAW resonator, the thickness of a piezoelectric film correlates with its resonant frequency. Specifically, the thicker the piezoelectric film is, the lower the resonant frequency of bulk wave vibration is.

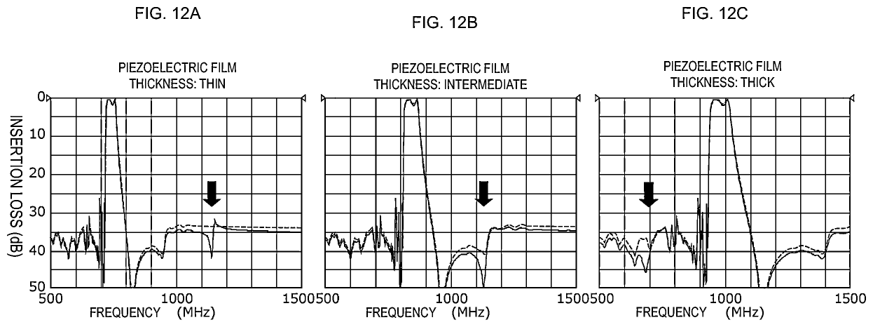

FIGS. 12A to 12C provide graphs illustrating the bandpass characteristic with respect to different film thicknesses of the piezoelectric film of the acoustic wave filter 2A according to the first practical example. As illustrated FIGS. 12A to 12C, as the thickness of the piezoelectric film 30a of the acoustic wave filter 2A increases from a relatively thin film to a relatively thick film, the attenuation pole (arrow in FIGS. 12A to 12C) moves from the higher-frequency side to the lower-frequency side.

Accordingly, by controlling the film thickness of the piezoelectric film 30a, attenuation can be achieved in a desired attenuation band. Moreover, when a plurality of BAW resonators are included as in the acoustic wave filter 2B according to the first modification and the acoustic wave filter 3B according to the fourth modification, two or more attenuation bands can be provided by configuring one BAW resonator of the plurality of BAW resonators differently from other BAW resonators.

### 5. Shape of Piezoelectric Film

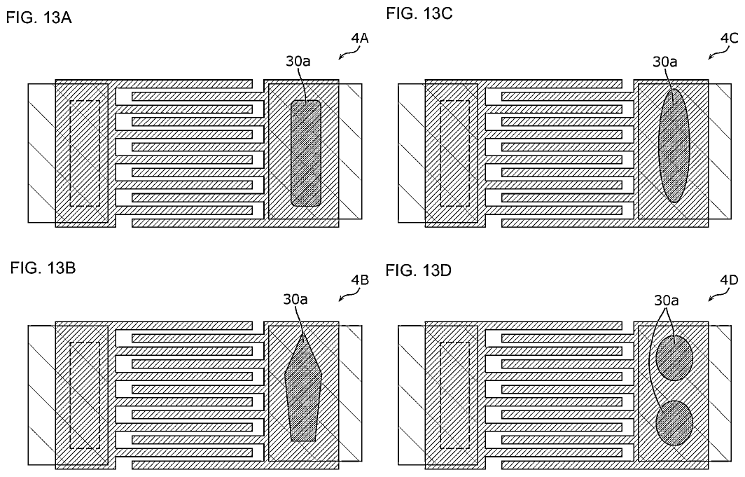

FIGS. 13A to 13D provide plan views of electrodes illustrating variations of the shape of the piezoelectric film 30a of the acoustic wave filter according to the above-described preferred embodiment. In the acoustic wave filter according to the above-described preferred embodiment, the piezoelectric film 30a may include curved corners when the substrate 10 is viewed in plan view, as in an acoustic wave filter 4A illustrated in FIG. 13A.

In the acoustic wave filter according to the above-described preferred embodiment, the piezoelectric film 30a may have a polygonal shape when the substrate 10 is viewed in plan view, as in an acoustic wave filter 4B illustrated in FIG. 13B.

In the acoustic wave filter according to the above-described preferred embodiment, the piezoelectric film 30a may have an oval or a circular shape when the substrate 10 is viewed in plan view, as in an acoustic wave filter 4C illustrated in FIG. 13C.

In the acoustic wave filter according to the above-described preferred embodiment, the piezoelectric film 30a may include a plurality of island-shaped areas when the substrate 10 is viewed in plan view, as in an acoustic wave filter 4D illustrated in FIG. 13D.

With the structure of the acoustic wave filters 4A to 4C, it is possible to reduce transverse-mode spurious responses as spurious waves unnecessary for vibrations of bulk acoustic wave in the BAW resonator. When the piezoelectric film is relatively small as in the acoustic wave filters 4A to 4C to reduce transverse-mode spurious responses, a plurality of piezoelectric films can be provided as illustrated in the acoustic wave filter 4D so that sufficient capacitance is provided between the upper electrode and the lower electrode.

As described above, the acoustic wave filter 1 according to the above-described preferred embodiment includes a SAW resonator and a BAW resonator. The SAW resonator includes the substrate 10 with piezoelectricity and the IDT electrode 20 on the substrate 10. The IDT electrode 20 includes the pair of comb-shaped electrodes 20a and 20b interdigitated with each other. Each comb-shaped electrode includes a plurality of electrode fingers extending parallel or substantially parallel in a direction crossing the SAW propagation direction and a busbar electrode connecting the plurality of electrode fingers to each other at one end of each electrode finger of the plurality of electrode fingers. The BAW resonator includes a lower electrode defined by a portion of the busbar electrode 110a, the piezoelectric film 30a provided on the busbar electrode 110a, and the upper electrode 40a provided on the piezoelectric film 30a.

With this structure, the acoustic wave filter 1 includes the SAW resonator and the BAW resonator on the same substrate. Additionally, the busbar electrode 110a of the SAW resonator also defines and functions as the lower electrode of the BAW resonator. This means that the SAW resonator and the BAW resonator are provided in a shared area on the substrate 10. Consequently, in comparison to the structure in which a SAW resonator and a BAW resonator are separately provided in discrete areas on a substrate, this structure can make the acoustic wave filter 1 smaller. Furthermore, because the busbar electrode 110a of the SAW resonator and the lower electrode of the BAW resonator can be formed at the same time, it is possible to simplify the manufacturing process and also reduce costs.

The piezoelectric film 30a may be mainly made of, for example, at least one of zinc oxide (ZnO), aluminum nitride (AlN), PZT, potassium niobate (KN), LN, LT, quartz-crystal, and lithium borate (LiBO).

The piezoelectric film 30a may be, for example, a c-axis oriented film made of zinc oxide (ZnO) or aluminum nitride (AlN).

When the substrate 10 is viewed in plan view, the piezoelectric film 30a may have a polygonal, a circular, or an oval shape, for example.

This structure can reduce transverse-mode spurious responses as spurious waves unnecessary for vibrations of bulk acoustic wave in the BAW resonator.

In the acoustic wave filter 2A according to the first practical example, the busbar electrode 110a and the lower electrode of the BAW resonator 60D may be coupled to the input-side ground wire 70b, and the upper electrode 40a of the BAW resonator 60D may be coupled to the radio-frequency-signal input-side wire 70a.

In the acoustic wave filter 3A according to the second practical example, the busbar electrode 111a and the lower electrode of the BAW resonator 62B may be coupled to the radio-frequency-signal output-side wire 70c, and the upper electrode 40a of the BAW resonator 62B may be coupled to the output-side ground wire 70d.

The acoustic wave filter 2A according to the first practical example and the acoustic wave filter 3A according to the second practical example may include a plurality of SAW resonators and a BAW resonator, the plurality of SAW resonators may determine the pass band of the acoustic wave filter, and the BAW resonator may determine an attenuation pole.

The acoustic wave filter 2B according to the first modification and the acoustic wave filter 3B according to the fourth modification may include a plurality of SAW resonators and a plurality of BAW resonators. The plurality of SAW resonators may include a plurality of IDT electrodes corresponding to the plurality of SAW resonators. The plurality of BAW resonators may include a first BAW resonator and a second BAW resonator. The first BAW resonator may include a first lower electrode defined by a portion of the busbar electrode of a first IDT electrode of the plurality of IDT electrodes, a first piezoelectric film provided on the busbar electrode, and a first upper electrode provided on the first piezoelectric film. The second BAW resonator may include a second lower electrode defined by a portion of the busbar electrode of a second IDT electrode of the plurality of IDT electrodes, a second piezoelectric film provided on the busbar electrode, and an upper electrode provided on the second piezoelectric film. The first piezoelectric film may be thinner than the second piezoelectric film, and the frequency at an attenuation pole determined by the first BAW resonator is higher than the frequency at an attenuation pole determined by the second BAW resonator.

In contrast to an acoustic wave filter including a single BAW resonator, this structure can achieve attenuation in two kinds of attenuation bands of different frequencies. As a result, in comparison to the structure in which the SAW resonators and the BAW resonators are separately provided in discrete areas on a substrate, this structure can further improve the attenuation characteristic of the acoustic wave filter and also make the acoustic wave filter smaller.

In the acoustic wave filter according to the first or second practical example or any of the first to sixth modifications, the plurality of SAW resonators may define a longitudinally coupled resonator. The longitudinally coupled resonator may include the IDT electrodes 20A to 20E corresponding to the plurality of SAW resonators. The IDT electrodes 20A to 20E may be adjacent to each other in the SAW propagation direction. The BAW resonator may include a lower electrode defined by a portion of the busbar electrode of a first IDT electrode of the IDT electrodes 20A to 20E, a piezoelectric film provided on the busbar electrode, and an upper electrode provided on the piezoelectric film. The upper electrode may be coupled to the busbar electrode of a second IDT electrode adjacent to the first IDT electrode.

With this structure of the acoustic wave filter including a longitudinally coupled resonator, in comparison to the structure in which the SAW resonators and the BAW resonators are separately provided in discrete areas on a substrate, it is possible to improve the attenuation characteristic of the acoustic wave filter and also make the acoustic wave filter smaller.

### Other Preferred Embodiments

The acoustic wave filter according to the present invention has been described with reference to a preferred embodiment of the present invention, practical examples, and modifications, but the present invention is not limited to the above-described preferred embodiment, practical examples, and modifications described above. The present invention also embraces other preferred embodiments including any combination of the elements of the above-described preferred embodiment, practical examples, and modifications, other modified examples obtained by making various modifications to the above-described preferred embodiment that occur to those skilled in the art without departing from the scope of the present invention, and various hardware devices including the acoustic wave filter of the present invention.

The first and second practical examples and the first to sixth modifications describe as an example the acoustic wave filter including a longitudinally coupled resonator, but the acoustic wave filter according to the present invention only needs to include one or more SAW resonators and one or more BAW resonators. For example, an acoustic wave filter according to a preferred embodiment of the present invention may be an acoustic wave ladder filter including a series arm SAW resonator and a parallel arm SAW resonator, and also include a BAW resonator including a lower electrode formed by a busbar electrode of the series arm SAW resonator or the parallel arm SAW resonator.

Further, at least either a series arm resonator or a parallel arm resonator may be coupled on the input-side or output-side with respect to the longitudinally coupled resonator included in the acoustic wave filter according to the first or second practical example or any of the first to sixth modifications.

In an acoustic wave filter according to a preferred embodiment of the present invention, an inductor and a capacitor may be coupled among the IDT electrodes and the wires. The inductor may include a wire inductor defined by a wire defining and functioning as an interconnection between elements.

Preferred embodiments of the present invention can be used as a small filter for a wide variety of wireless communication terminals required to achieve low loss performance in the pass band and high attenuation performance outside the pass band.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter comprising:
a surface acoustic wave resonator and a bulk acoustic wave resonator; wherein
the surface acoustic wave resonator includes:
a substrate with piezoelectricity; and
an interdigital transducer (IDT) electrode on the substrate;
the IDT electrode includes a pair of comb-shaped electrodes interdigitated with each other, each of the pair of comb-shaped electrodes including a plurality of electrode fingers extending in parallel or substantially in parallel in a direction crossing a surface acoustic wave propagation direction and a busbar electrode connecting the plurality of electrode fingers to each other at one end of each electrode finger of the plurality of electrode fingers; and
the bulk acoustic wave resonator includes:
a lower electrode including a portion of the busbar electrode;
a piezoelectric film on the busbar electrode; and
an upper electrode on the piezoelectric film.

2. The acoustic wave filter according to claim 1, wherein the piezoelectric film mainly includes at least one of zinc oxide (ZnO), aluminum nitride (AlN), PZT, potassium niobate (KN), LN, LT, quartz-crystal, or lithium borate (LiBO).

3. The acoustic wave filter according to claim 2, wherein the piezoelectric film is a c-axis oriented film including zinc oxide (ZnO) or aluminum nitride (AlN).

4. The acoustic wave filter according to claim 1, wherein, when the substrate is viewed in plan view, the piezoelectric film has a polygonal, a circular, or an oval shape.

5. The acoustic wave filter according to claim 1, wherein
the busbar electrode and the lower electrode are coupled to a ground wire; and
the upper electrode is coupled to a radio-frequency-signal input-output wire.

6. The acoustic wave filter according to claim 1, wherein
the busbar electrode and the lower electrode are coupled to a radio-frequency-signal input-output wire; and
the upper electrode is coupled to a ground wire.

7. The acoustic wave filter according to claim 1, wherein
the acoustic wave filter includes a plurality of the surface acoustic wave resonators, and the bulk acoustic wave resonator;
the plurality of surface acoustic wave resonators determine a pass band of the acoustic wave filter; and
the bulk acoustic wave resonator determines an attenuation pole.

8. The acoustic wave filter according to claim 7, the acoustic wave filter includes a plurality of the bulk acoustic wave resonators; wherein
the plurality of surface acoustic wave resonators include a plurality of IDT electrodes corresponding to the plurality of surface acoustic wave resonators;
the plurality of bulk acoustic wave resonators include a first bulk acoustic wave resonator and a second bulk acoustic wave resonator;
the first bulk acoustic wave resonator includes a first lower electrode defined by a portion of the busbar electrode of a first IDT electrode of the plurality of IDT electrodes, a first piezoelectric film on the busbar electrode, and a first upper electrode on the first piezoelectric film;
the second bulk acoustic wave resonator includes a second lower electrode defined by a portion of the busbar electrode of a second IDT electrode of the plurality of IDT electrodes, a second piezoelectric film on the busbar electrode, and an upper electrode on the second piezoelectric film; and
the first piezoelectric film is thinner than the second piezoelectric film, and a frequency at an attenuation pole determined by the first bulk acoustic wave resonator is higher than a frequency at an attenuation pole determined by the second bulk acoustic wave resonator.

9. The acoustic wave filter according to claim 7, wherein
the plurality of surface acoustic wave resonators define a longitudinally coupled resonator;
the longitudinally coupled resonator includes a plurality of IDT electrodes corresponding to the plurality of surface acoustic wave resonators;
the plurality of IDT electrodes are adjacent to each other in the surface acoustic wave propagation direction;
the bulk acoustic wave resonator includes a lower electrode defined by a portion of the busbar electrode of a first IDT electrode of the plurality of IDT electrodes, a piezoelectric film on the busbar electrode, and an upper electrode on the piezoelectric film; and
the upper electrode is coupled to the busbar electrode of a second IDT electrode adjacent to the first IDT electrode.

10. The acoustic wave filter according to claim 1, wherein the substrate is a single-crystal piezoelectric substrate.

11. The acoustic wave filter according to claim 10, wherein the single-crystal piezoelectric substrate includes at least one of LiNbO₃, LiTaO₃, or quartz-crystal.

12. The acoustic wave filter according to claim 1, wherein the substrate includes a high acoustic velocity support substrate, a low acoustic velocity film, and a piezoelectric film stacked in this order.

13. The acoustic wave filter according to claim 12, wherein the high acoustic velocity support substrate includes silicon.

14. The acoustic wave filter according to claim 12, wherein the low acoustic velocity film includes silicon dioxide.

15. The acoustic wave filter according to claim 1, wherein the IDT electrode includes a fixing layer and a main electrode layer on the fixing layer.

16. The acoustic wave filter according to claim 15, wherein the fixing layer includes Ti.

17. The acoustic wave filter according to claim 15, wherein the main electrode layer includes Al including about 1% Cu.

18. The acoustic wave filter according to claim 1, wherein the IDT electrode includes at least one of Ti, Al, Cu, Pt, Au, Ag, or Pd, or an alloy including at least one of Ti, Al, Cu, Pt, Au, Ag, or Pd.
